(19) United States
(12) Patent Application Publication
(10) Pub. No.: US 2008/0224786 A1
(43) Pub. Date: Sep. 18, 2008

(54) Apparatus and method for temperature compensating an ovenized oscillator

(76) Inventors: James L. Stolpman, Bloomingdale, IL (US); Thomas A. Knecht, Dundee, IL (US); Jerry L. Shirar, Hanover Park, IL (US)

Correspondence Address: DANIEL J. DENEUFBOURG;CTS CORPORATION, 171 COVINGTON DRIVE, BLOOMINGDALE, IL, 60108, US

(21) Appl. No.: 12/075,589

(22) Filed: Mar. 12, 2008

Related U.S. Application Data
(60) Provisional application No. 60/906,681, filed on Mar. 13, 2007.
(60) Provisional application No. 60/993,826, filed on Sep. 14, 2007.

(51) Int. Cl. H03B 5/04; H03L 1/04

(52) U.S. Cl. 331/66; 331/69

(57) ABSTRACT

An oscillator assembly includes an oscillator circuit that is configured to generate a frequency signal. A temperature compensation circuit is in communication with the oscillator circuit and adapted to adjust the frequency signal in response to changes in temperature. The oscillator and temperature compensation circuits are located within an oven. A heater and a temperature sensor in communication with the heater are also both located in the oven. The temperature sensor is adapted to directly control the heater in response to changes in temperature. In one embodiment, the oscillator components are mounted to a ball grid array substrate which, in turn, is mounted on a printed circuit board. In this embodiment, a resonator overlies the ball grid array substrate and a lid covers and defines an oven and enclosure for the resonator and the ball grid array substrate. The oscillator and temperature compensation circuit are defined on the ball grid array substrate.

### CROSS-REFERENCE TO RELATED APPLICATIONS

This application claims the benefit of the filing dates and disclosures of U.S. Provisional Application Ser. No. 60/906,681, filed on Mar. 13, 2007; and U.S. Provisional Application Ser. No. 60/993,826, filed on Sep. 14, 2007 which are explicitly incorporated herein by reference as are all references cited therein.

### FIELD OF THE INVENTION

This invention relates to oscillators that can provide a stable reference frequency signal in electronic equipment. Specifically, this invention relates to a temperature compensated oscillator contained within a heated enclosure to increase the stability of the reference frequency signal.

### DESCRIPTION OF THE RELATED ART

Oscillators are well known devices for providing a reference frequency source. The oscillator typically has a quartz crystal or other resonator and also has electronic compensation circuitry to stabilize the output frequency.

Various methods are known for stabilizing the output frequency as the temperature of the oscillator changes. Temperature compensated crystal oscillators (TCXO) typically employ thermistors which generate a correction voltage that reduces the frequency variation over temperature. The correction voltage is usually applied to a varactor diode in the crystal circuit such that the crystal frequency may be varied by a small amount.

To obtain a more stable output, ovenized oscillators (OCXO) heat the temperature sensitive portions of the oscillator which are isolated from the ambient to a uniform temperature. Ovenized oscillators contain a heater, a temperature sensor, and circuitry to control the heater. The temperature control circuitry holds the crystal and critical circuitry at a precise, constant temperature. The best controllers are proportional, providing a steady heating current which changes with the ambient temperature to hold the oven at a precise set-point, usually about 10 degrees Centigrade above the highest expected ambient temperature.

### SUMMARY OF THE INVENTION

It is a feature of the invention to provide a low cost, high performance temperature compensated ovenized oscillator that provides a stable frequency signal regardless of changes in temperature.

In one embodiment of the invention, the oscillator includes a printed circuit board that has first and second surfaces, a substrate that has third and fourth surfaces and an enclosure defining a temperature controlled oven. The printed circuit board and the substrate are located within the enclosure. Several conductive balls are electrically connected between the first and fourth surfaces. An oscillator circuit is defined on the third surface and a temperature compensation circuit is in communication with the oscillator circuit. The temperature compensation circuit and a heater are also defined on the third surface. A resonator which, in one embodiment, is coupled to the substrate at least partially overlies the heater.

Thus, in one embodiment, the oscillator assembly comprises a first substrate, a second substrate mounted to the top of the first substrate, an oscillator and temperature compensation circuit both defined on the top of the second substrate, a temperature sensor having at least a portion thereof mounted to the top of the second substrate, and a crystal located above the second substrate. A heater is mounted to the second substrate. The second substrate is preferably a ceramic ball grid array substrate and a plurality of conductive balls couple the first and second substrates. A cover is mounted over the first and second substrates. The crystal extends over at least the heater and the temperature sensor.

A further feature of the invention is to provide an oscillator assembly that includes a housing and a substrate mounted in the housing. An oscillator circuit is mounted to the substrate and a resonator is mounted to the substrate and is in communication with the oscillator circuit. A temperature compensation circuit is mounted to the substrate and is in communication with the oscillator circuit. A field effect transistor is mounted to the substrate. The field effect transistor has a source, a gate and a drain. A thermistor is mounted to the substrate and is connected to the gate. The thermistor is adapted to control a gate voltage in response to changes in temperature.

An additional feature of the invention is to provide an oscillator assembly that includes an oscillator circuit that is configured to generate a frequency signal. A temperature compensation circuit is in communication with the oscillator circuit. The temperature compensation circuit is adapted to adjust the frequency signal in response to changes in temperature. The oscillator and the temperature compensation circuit are located within an oven. A heater is located in the oven and a temperature sensor is located in the oven and is in communication with the heater. The temperature sensor is adapted to control the heater in a non-linear manner in response to changes in temperature. The response of the heater to a change in temperature is slower than the rate of change in temperature. The heater includes a field effect transistor and the temperature sensor includes a thermistor.

A method of operating an oscillator in accordance with the invention includes the steps of initially providing a temperature compensated crystal oscillator which is located within an enclosure and produces a frequency signal. A first temperature is measured within the enclosure using a first temperature sensor. A field effect transistor is controlled using the first temperature sensor. A second temperature is measured within the enclosure and the frequency signal is adjusted based on the second temperature. The field effect transistor has a gate threshold voltage that increases as the temperature decreases. This reduces a portion of the increase in voltage at the gate due to the change in the thermistor resistance. The current through the field effect transistor is thereby less than it would be if the gate threshold voltage were constant over temperature.

In accordance with the invention, a gate threshold voltage change and transconductance combine to provide insufficient gain to keep the temperature inside the oven at a nearly constant temperature, but allows the temperature inside the oven to drop as the outside ambient temperature drops in a manner in which the temperature inside the oven may or may not be linear with respect to the change in ambient temperature.

Those skilled in the art will appreciate that the conception, upon which this disclosure is based, may readily be utilized as a basis for the designing of other structures, methods and systems for carrying out the several purposes of the present invention. Further, the abstract is neither intended to define the invention of the application, which is measured by the claims, nor is it intended to be limiting as to the scope of the invention in any way.

### BRIEF DESCRIPTION OF THE DRAWINGS

These and other features of the invention can best be understood by the following description of the accompanying drawings as follows:

FIG. 1 is a diagrammatic or block view/diagram of an embodiment of a temperature compensated ovenized oscillator in accordance with the present invention;

FIG. 2 is a schematic view of a temperature compensated ovenized oscillator in accordance with the present invention;

FIG. 3 is an isometric, perspective view of a physical implementation of an oscillator assembly incorporating the oscillator circuit of FIG. 2;

FIG. 4 is a top plan view of the oscillator assembly shown in FIG. 3 with the housing removed;

FIG. 5 is a side part cross-sectional, part elevational view of the oscillator assembly of FIG. 3;

FIG. 6 is a bottom plan view of the oscillator assembly of FIG. 3;

FIG. 7 is a top plan view of the ball grid array substrate located in the interior of the oscillator assembly of FIG. 3;

FIG. 8 is a bottom plan view of the ball grid array substrate of FIG. 7;

FIG. 9 is a top plan view of the printed circuit board also located in the interior of the oscillator assembly of FIG. 3;

FIG. 10 is a bottom plan view of the printed circuit board of FIG. 9;

FIG. 11 is a graph of temperature within the housing versus ambient temperature for the oscillator of FIG. 2; and

FIG. 12 is a graph of voltage versus temperature for the gate voltage, the gate to source threshold voltage, and the effective gate voltage for the oscillator of FIG. 2.

It is noted that the drawings of the invention are not to scale.

### DETAILED DESCRIPTION

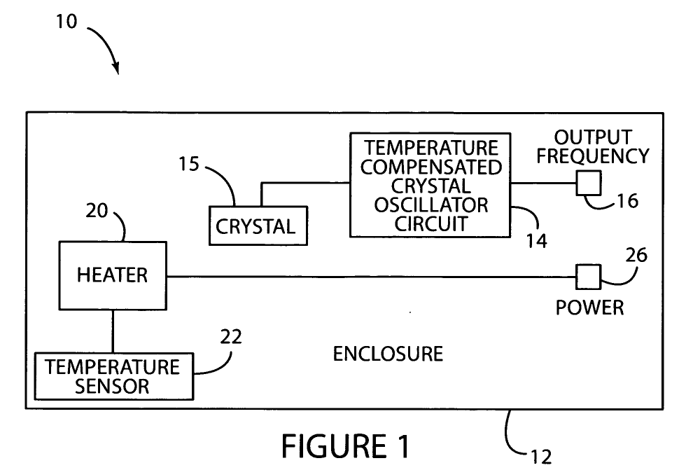

A diagrammatic block diagram of a Temperature Compensated Ovenized Oscillator (TCOCXO) is shown in FIG. 1. Oscillator assembly 10 includes a metal lid or cover 12 with or without insulation which defines an interior housing, enclosure or oven 32 which contains the oscillator components. A temperature compensated crystal oscillator circuit (TCXO) 14 that is in communication with a resonator or crystal 15 is located in oven 32. TCXO 14 can be a Pierce or Colpitts oscillator circuit using an AT cut quartz crystal. TCXO 14 provides a stable reference frequency at output terminal 16. TCXO 14 may also be comprised of separate oscillator and temperature compensation circuits.

A heater 20 is located in oven 32. Heater 20 can comprise a transistor in which the dissipated power is controlled to heat and maintain a temperature range inside oven 32. A temperature sensor 22 is located in proximity to oven 32. Temperature sensor 22 can comprise a negative coefficient conventional thermistor. Temperature sensor 20 directly controls heater 20.

When the temperature in the oven 32 decreases, temperature sensor 22 causes heater 20 output to keep the temperature in oven 32 within the range over which TCXO 14 is optimized to operate. When the temperature in the oven increases, temperature sensor 22 reduces power to heater 20 to keep the temperature in oven 32 within the range over which TCXO 14 is optimized to operate.

In accordance with the invention, heater 20 is never turned off and always supplies some level of heat within oven 32.

### Circuit

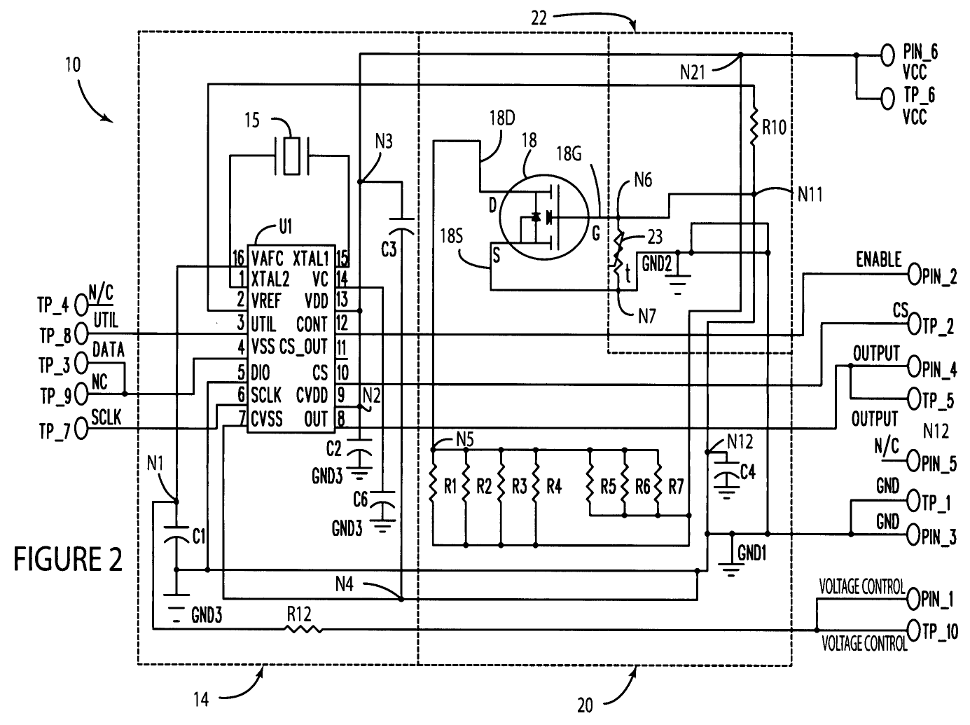

A schematic circuit diagram of oscillator assembly 10 is shown in FIG. 2. Oscillator assembly 10 includes a temperature compensation circuit 14, a crystal 15, a heater or heater circuit 20, and a temperature sensor or temperature sensor circuit 22.

Temperature compensated crystal oscillator circuit (TCXO) 14 can include a temperature compensated oscillator integrated circuit U1. Integrated circuit U1 includes a Pierce oscillator circuit, a temperature compensation circuit, and an internal temperature sensor. Other oscillator configurations such as Colpitts or Clapp could also be used without any loss in performance.

Integrated circuit U1 has a voltage control terminal Vafc, crystal terminals Xtal1 and Xtal2, ground terminal Cvss, RF output terminal OUT, power supply terminal Vdd, clock terminal Sclk, data terminal Vss, enable terminal Cont, reference voltage terminal Vref and terminals Dio, Util and Csout.

An AT cut quartz crystal 15 is connected across crystal terminals Xtal1 and Xtal2. Other types of resonators could also be used such as SC cut quartz crystals, SAW or BAW resonators, or lithium niobate resonators.

Capacitor C1 is connected between Node N1 and ground. Capacitor C2 is connected between node N2 and ground. Capacitor C3 is connected between nodes N3 and N4. Capacitor C6 is connected between terminal Vc and ground. Resistor R12 is connected between node N1 and the voltage control terminal.

Heater 20 includes a Metal Oxide Semiconductor Field Effect Transistor (MOSFET) having a gate 18G, drain 18D, and source 18S. Gate 18G is connected to node N6. Drain 18D is connected to node N5, and source 18S is connected to node N7, which is connected to ground.

Heater 20 further includes resistors R1, R2, R3, R4, R5, R6 and R7 that are connected in parallel between nodes N5 and N12. Node N12 is in common with nodes N21. Node N21 is connected to power source Vcc. Resistor R10 is connected between node N11 and terminal Vref. Node N11 is commoned with node N6. Capacitor C4 is connected between node N12 and ground.

Resistors R1-R7 limit the maximum current during start up conditions. Because resistors R1-R7 are connected with transistor drain 18D, the gate to source voltage does not change as the current in field effect transistor changes. Resistors R1-R7 also provide heat within oven 32.

Heater 20 is directly controlled by a temperature sensor or temperature sensor circuit 22 that is connected to node N6 or to transistor gate 18G. Temperature sensor 22 can include the voltage divider combination of resistor R10 and a negative coefficient conventional thermistor 23 that is coupled directly or indirectly to transistor gate 18G. Temperature sensor 22 changes resistance in response to changes in temperature surrounding temperature sensor 22.

Oscillator assembly 10 has several terminals or pins that connect with the circuit. Terminal VCC is connected to node N3. The Enable terminal is connected to terminal Cont of integrated circuit U1 for enabling purposes. Terminal output is the RF output frequency terminal. Terminal voltage control provides external access to the oscillator control voltage signal. Terminal GND is connected to nodes N2, N12 and ground.

Terminals TP1, TP2, TP3, TP4, TP5, TP6, TP7, TP8, TP9 and TP10 are connected to the various points on oscillator assembly 10 and provide access for programming and calibration of the oscillator assembly during manufacturing.

### Oscillator Package

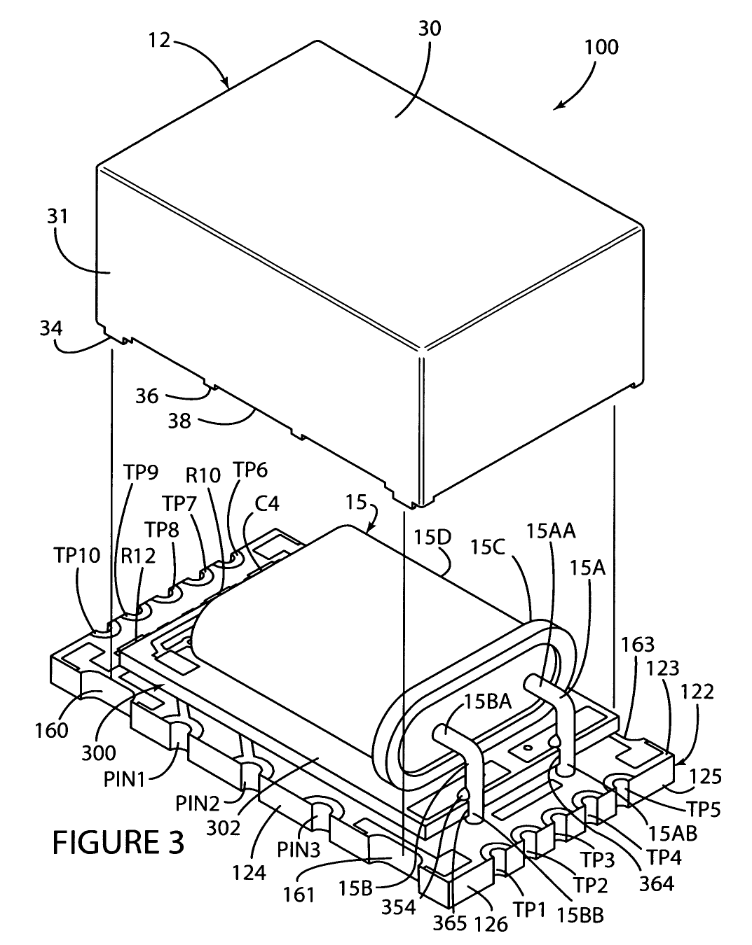

FIGS. 3-10 show the physical layout or packaging of Temperature Compensated Ovenized Oscillator or (TCOCXO) assembly 10. Oscillator assembly 10 can be packaged in a module 100. The module 100 which, in the embodiment shown, has a nominal size of about 14.3 mm (length)×9.3 mm (width)×7.0 mm (height), includes a generally planar rectangular-shaped printed circuit board 122 including a top face 123 on which all of the electrical and electronic components defining the oscillator are appropriately mounted and interconnected together with a metal cover or lid 12 which covers all of the components. Although not shown, it is understood that the printed circuit board 122 is a GETEK™ board made of a plurality of conventional electrically insulative laminates.

Cover 12 is generally rectangular in shape and defines hollow interior cavity or oven 32 (FIG. 5). Cover 12 is open on one side. Cover 12 has a top surface or roof 30 and four downwardly depending side surfaces or walls 31 that are joined to define cavity/oven 32. Walls 31 are oriented in a generally perpendicular relationship to roof 30. Walls 31 have a lower peripheral edge 38 that extends circumferentially around cover 12. Several tabs 34 extend downwardly from the lower peripheral edge 38.

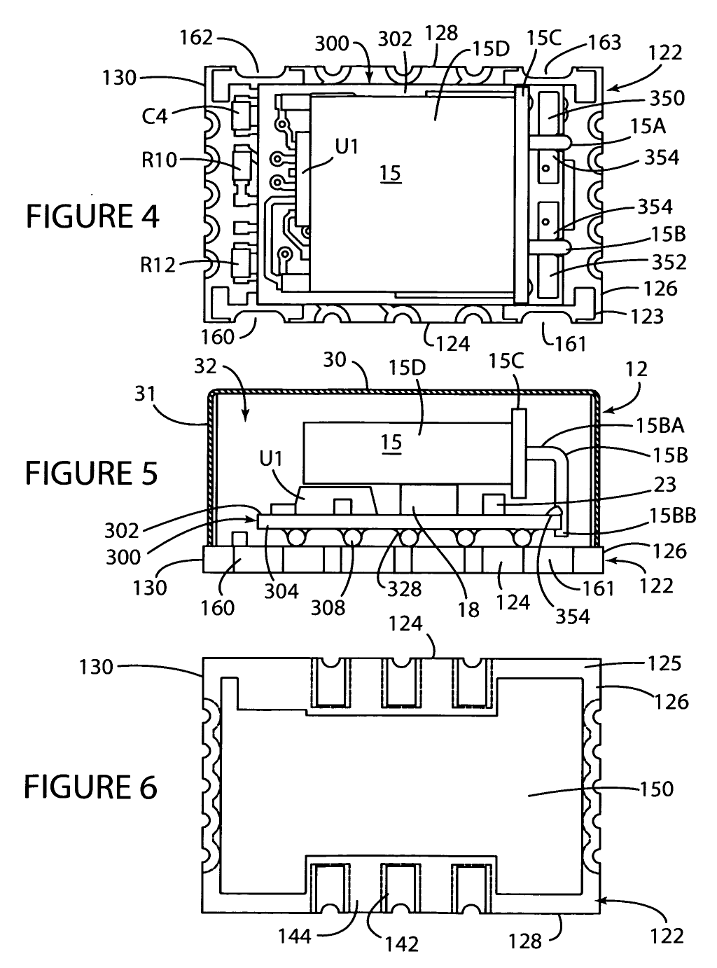

Printed circuit board 122 is planar in shape and includes respective front and back (top and bottom) sides or faces 123 (FIGS. 3 and 4) and 125 (FIG. 6) and respective elongate side peripheral edges 124, 126, 128 and 130.

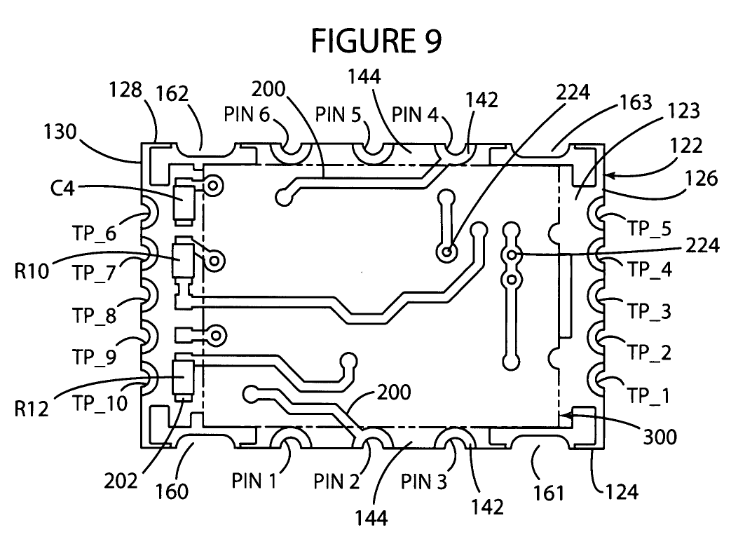

A first plurality of castellation pins PIN1-PIN3 (FIGS. 3 and 9), defining direct surface mount pads or pins, are formed and extend along the length of the board side edge 124 in spaced-apart and parallel relationship.

A second plurality of castellation pins PIN4-PIN6 (FIG. 9), also defining respective direct surface mount pads or pins, are formed and extend along the length of the board side edge 128 in spaced-apart and parallel relationship.

A third plurality of castellation pins TP1-TP5 (FIGS. 3 and 9), also defining respective direct surface mount pads or pins, are formed and extend along the length of the board side edge 126 in spaced-apart and parallel relationship.

A fourth plurality of castellation pins TP6-TP10 (FIG. 9), also defining respective direct surface mount pads or pins, are formed and extend along the length of the board side edge 130 in spaced-apart and parallel relationship.

Each of the castellations is defined by a generally semi-circularly shaped elongate groove which is formed in the respective side edges 124, 126, 128 and 130; extends between the top and bottom faces 123 and 125 of board 122 in an orientation generally normal thereto; and is covered/coated with a layer of conductive material so as to define a path for electrical signals between the top and bottom faces 123 and 125 of board 122.

The castellations are adapted to be seated against the respective pads or pins of a motherboard to which module 100 is adapted to be direct surface mounted as known in the art. The castellations correspond to the terminals and pins previously described with reference to FIG. 2.

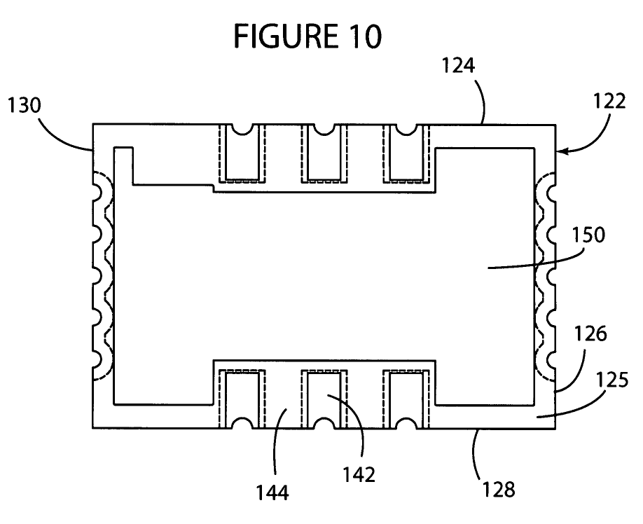

Each of the grooves defined by the non-ground castellations in the respective top and bottom faces 123 and 125 are surrounded by a region/layer 142 (FIGS. 6 and 10) of conductive material which, in turn, is surrounded by a region 144 (FIGS. 6 and 10) which is devoid of conductive material so as to separate the respective input and output pins from ground.

The operative specifications for the module 100 are summarized in Table 1 below:

TABLE 1

| | Min. | Typical | Max. | Units |
|---|---|---|---|---|
| Frequency | | 19.2 | | MHz |
| Tuning voltage range | 0.5 | | 3.0 | VDC |
| Operating temperature range | 0 | | 70 | ° C. |
| Supply voltage | | 3.3 | | VDC |
| Supply power (steady state) | | | 1 | watt |
| Stability | | | 100 | ppb |
| Phase Noise @ 10 kHz offset | | | −140 | dBc/Hz |

The location of each of the electrical/electronic components on the printed circuit board 122 of module 100 is shown in FIGS. 9 and 10 with FIG. 9 depicting the front or top face 123 of the board 122 and FIG. 10 depicting the back or bottom face 125 of the board 122.

Front face 123 has both a plurality of conductive wiring traces 200 and a plurality of connected conductive mounting sites or pads 202 formed thereon for mounting and interconnecting the various electrical/electronic components including resistors, a thermistor, and a ceramic substrate as described in more detail below.

The conductive wiring traces 200 can be connected with various castellations and plated through holes 224. Plated through-holes 224 extend through the board 122 in a relationship generally normal to the top and bottom faces 123 and 125. The plated through-holes 224 are coated with conductive material and serve the purpose of making electrical connections between the top 123 and the bottom 125 of printed circuit board 122. A portion of the plated through holes 224 extend onto faces 123 and 125. The various electronic components can be attached to top face 123 by soldering as is known in the art.

Resistors R10 and R12 and a capacitor C4 are mounted on the top face 123 to mounting pads 202. Also mounted on top face 123 of board 122 is a ball grid array ceramic substrate (BGA) 300 (FIG. 5) that further holds additional electronic components. BGA substrate 300 is soldered to select plated through holes 224. The upper face 123 still further defines four notches 160, 161, 162 and 163 formed generally toward each corner of board 122. Notches 160-163 extend down from top face 123 approximately half way toward bottom face 125. Notches 160-163 serve the purpose of accepting the tabs 34 of the metal lid 127.

Referring now to FIG. 10, the lower side or face 125 of board 122 includes a ground layer of conductive material 150 which covers a majority of the surface thereof. Ground layer 150 can server to reduce EMI noise and as an impedance reference plane.

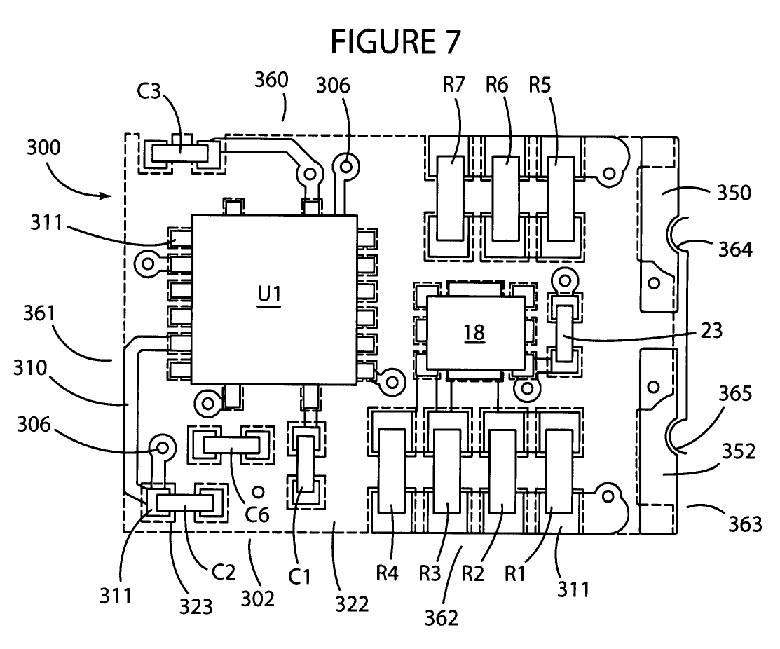

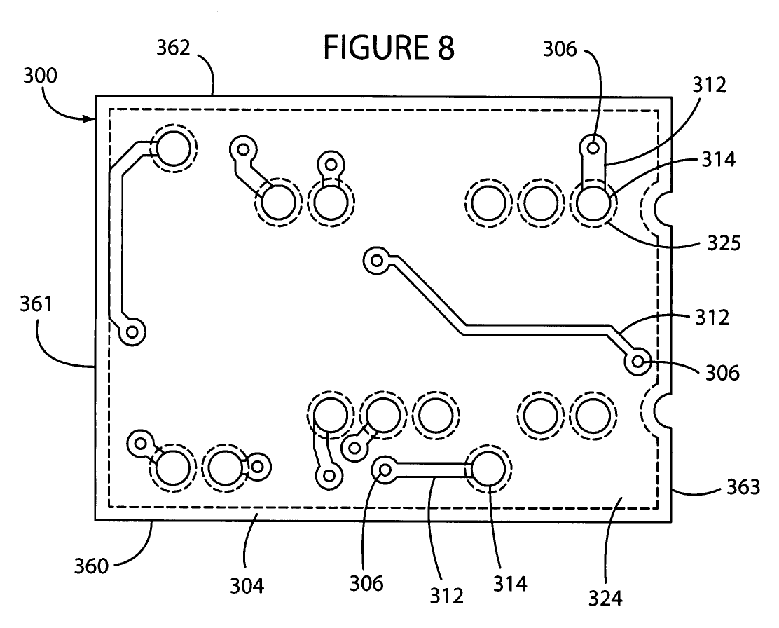

The other components of the temperature compensated crystal oscillator circuit 14, i.e., heater 20 and thermistor 23 are mounted on ball grid array ceramic substrate (BGA) 300. Details of the ball grid array ceramic (BGA) substrate 300 are shown in FIGS. 6-8. BGA 300 is generally rectangular in shape and include a top surface 302 (FIG. 5), bottom surface 304 (FIG. 8) and four peripheral side surfaces 360, 361, 362 and 363 (FIGS. 7 and 8). A pair of grooves or notches 364 and 365 are located on side 363 extending between top surface 302 and bottom surface 304. Substrate 300 can be made of various ceramic materials such as alumina.

Several conductive vias 306 (FIG. 8) extend between top and bottom surfaces 302 and 304 respectively. Vias 306 partially extend onto top surface 302 and bottom surface 304. Several conductive spheres or balls 308 (FIG. 5) are mounted to selected conductive vias 306 on bottom surface 304. Conductive balls 308 are electrically connected to vias 306. Conductive balls 308 is formed from several different materials such as solder, conductive epoxy, metals or plated plastic or ceramic balls.

BGA substrate 300 further define several conductive lines 310, mounting pads 311 and crystal lead pads 350 and 352 on top surface 302 and several conductive lines 312 and ball pads 314 on bottom surface 304. Ball pads 314 are connected to vias 306.

The conductive lines 310 make electrical connections with and between vias 306 and mounting pads 311. The conductive lines 312 make electrical connections with and between vias 306 and ball pads 314. Some of conductive lines 312 are connected between pairs of vias 306.

Ball pads 314 are electrically and mechanically connected to conductive balls 308 by a conductive material such as a reflowed solder alloy or conductive epoxy 328 (FIG. 5).

An insulating covercoat 322 can cover the majority of top surface 302 except where openings 323 are formed above mounting pads 311 and crystal lead pads 350 and 352.

Similarly, insulating covercoat 324 can cover the majority of bottom surface 304 except where openings 325 are formed above ball pads 314.

The location of each of the electrical/electronic components on BGA substrate 300 is shown in FIGS. 7 and 8 with FIG. 7 depicting the top surface 302 and FIG. 8 depicting the bottom surface 304.

Resistors R1, R2, R3, R4, R5, R6 and R7; capacitors C1, C2, C3 and C6; integrated circuit U1; FET transistor 18; and thermistor 23 are all mounted to pads 311 on the top surface 302.

Resistors R1, R2, R3, R4 and capacitors C1, C2 and C6 are generally positioned on the right half of top substrate surface 302 adjacent to, and generally normal to, side surface 362. Resistors R5, R6, R7 and capacitor C3 are also generally positioned on the right half of top substrate surface 302 adjacent, and generally normal to, opposed side surface 360. Integrated circuit U1 is located toward side 361 on top surface 302. FET transistor 18 is located on top substrate surface 302 toward the center of substrate 300 and between the respective banks of capacitors R5, R6, R7 and R1, R2, R3, and R4. Thermistor 23 is positioned on top substrate surface 302 between the transistor 18 and side 363.

With additional reference to FIGS. 3, 4 and 5, it is noted that crystal 15 is oriented and positioned within the interior of oven/enclosure 32 in a relationship overlying and spaced from the BGA substrate 300 wherein crystal 15 overlies FET transistor 18, integrated circuit U1, and thermistor 23. Transistor 18 may be in contact with the underside of crystal 15 such that FET transistor 18 can readily transfer heat to crystal 15 when FET transistor 18 is operating. FET transistor 18 is located between the substrate 300 and crystal 15. A heat transfer compound such as a thermal grease or adhesive may be used between FET transistor 18 and crystal 15 in order to enhance the transfer of heater between FET transistor 18 and crystal 15.

Crystal 15 further includes L-shaped leads 15A and 15B that extend downwardly adjacent to, and into contact with, side surface 363 of BGA 300. Lead 15A is positioned in groove 364 and lead 15B is positioned in groove 365. Lead 15A is electrically connected to crystal lead pad 350 by solder 354. Lead 15B is electrically connected to crystal lead pad 352 by solder 354.

Crystal 15 can be a can type crystal that resonates at 19.2 MHz. The electronic components can be electrically connected to pads 311 by a conductive material such as a solder alloy.

With continued reference to FIGS. 3-5, crystal 15 has an outer metal can 15D that is attached to a base 15C and is spaced from the underside of roof 30 of enclosure 12. Leads 15A and 15B curve downwardly from base 15C in the direction of BGA substrate 300. Lead 15A has ends 15AA and 15AB. Lead 15B has ends 15BA and 15BB. Ends 15AA and 15BA extend outwardly from base 15C. End 15AB is attached or coupled by solder 354 to crystal lead pad 350 on BGA 300. End 15BB is attached or coupled by solder 354 to crystal lead pad 352 also on BGA 300. Can 15D extends over and parallel to a large portion of top surface 302.

Thermistor 23 is oriented and positioned adjacent to crystal 15 and is located between BGA substrate 300 and metal can 15D of crystal 15. Thermistor 23 may be positioned in contact with crystal 15 to allow thermistor 23 to sense a highly accurate temperature reading or signal of the current temperature of crystal 15. The highly accurate temperature signal can be used to control heater 20.

An optional thermal adhesive (not shown) may be used between crystal 15 and field effect transistor 18 or thermistor 23.

This particular arrangement and positioning of the various components defining the module 100 of the present invention in the relationship wherein BGA substrate 300 (and all the components thereon) is seated on the top surface of printed circuit board 122, the crystal 15 overlies the BGA substrate 300, and the cover 12 overlies and covers the board 122, BGA substrate 300, and the crystal 15 allows for a compact package with good noise characteristics.

As described above, outer metal cover 12 is adapted to be fitted over the top face 123 of board 122. Cover 12 includes four tabs 34 that extend downwardly from side walls 31 and are adapted to be fitted or engaged into the respective notches 160-163 defined in the top face 123 of board 122. The notches and tabs, in combination, locate and secure the cover 12 to the board 122. Cover 12 may be filled with insulation (not shown) if desired. Cover 12 serves the purpose of an enclosure and isolates the electronic components from large thermal gradients.

Each of the side walls 31 defines a peripheral edge 36. Several notches 38 extend into the respective edge 34 thereof and are all appropriately positioned along the length of the respective side walls 31 so as to overlie the respective castellations and prevent shorting between the castellations.

### Operation

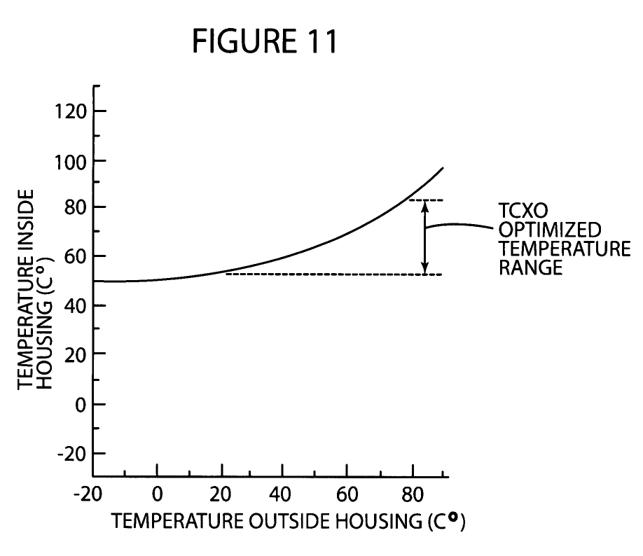

Oscillator assembly 10 is designed to operate over a range of temperatures. For example, with reference to FIG. 11, when the temperature outside oven 32 varies over the normal ambient temperature range the device is designed to operate, heater 20 is controlled by temperature sensor 22 such that the current to heater 20 is varied to maintain a temperature range within oven 32 that is some fractional part of the full ambient temperature range.

When the ambient temperature increases, the current to heater 20 is reduced but maintains the temperature within the range over which TCXO circuit 14 has been optimized to operate. It is noted that heater 20 is still operational throughout the complete range of ambient temperatures at which the device is exposed to and is designed not to hold a specific temperature but a significant temperature range between about 10% to 40% of the full ambient temperature range.

Therefore, the present invention allows for the operation of TCXO circuit 14 to be optimized over the temperature range that is only about 10% to 40% of the full ambient temperature range as in prior art TCXO devices. The optimization over a narrower temperature range allows for frequency stability to increase to less than 100 pbb from the 1-2 ppm of the prior art devices.

During operation of oscillator assembly 10, temperature sensor 22 directly controls the operation of heater 20 in response to temperature changes sensed by thermistor 23. Thermistor 23 is mounted within cover 12 and oven 32 in an area that is close to crystal 15. The use of temperature sensor 22 to directly control heater 20 eliminates the need for a proportional oven controller.

Temperature sensor 22 is used to control the heater 20 within a certain temperature range in which the TCXO circuit 14 has been compensated to account for the frequency changes within a smaller or reduced temperature range. Heater 20 does not have a maximum current that limits the lower ambient temperature range in which the device operates or causes the TCXO circuit 14 to compensate when the internal temperature drops below a pre-defined temperature.

The range of temperatures within the oven 32 is such that TCXO circuit 14 can compensate for the changes in temperature to a much greater degree than it could compensate over the full ambient temperature range to which the oscillator assembly is exposed.

One unique aspect of oven 32 is that the temperature within the oven 32 is loosely controlled so that the temperature within oven 32 is not proportional to the temperature outside the oven 32. In other words, the temperature inside the oven 32 does not change linearly with temperature changes outside the oven 32. The temperature inside the oven 32 lags the temperature outside the oven 32 in a non-linear manner. This results in lower power consumption.

Another unique aspect of the present invention is that the heater 20 is not allowed to turn off over the ambient temperature range over which the oscillator assembly is designed to operate.

If the heater 20 were allowed to turn off, the thermal model of an ovenized TCXO would be reversed from an oscillator with an inside heater to a device with an outside heater. The point at which this transition occurs results in undesired frequency changes due to crystal and temperature sensor (the sensor used for temperature compensation of the oscillator) placement making the location of the sensor critical to good frequency stability. This invention eliminates the transition region or temperature at which the heating element is turned on or off and makes the placement of the temperature sensor for the TCXO compensation circuit much less critical.

The present invention also allows for more flexibility in the placement and position of the crystal, heater and temperature sensor because the temperature within the oven 32 does not have to be as tightly controlled. Oscillator assembly 10 can provide frequency stability on the order to 100 ppb. Because the temperature within oven 32 is not tightly controlled, fewer and less expensive components with greater tolerances can be utilized resulting in a lower cost device.

Oven 32 uses the characteristics of FET transistor 18 and thermistor 23 to provide a loosely controlled temperature range instead of a proportional controller which attempts to hold a constant temperature. Oven 32 provides a temperature range within the oven 32 that is approximately 25 to 30 percent of the ambient temperature range outside the oven 32.

With additional reference to FIG. 2, the gate voltage at node N6 is controlled by the voltage divider comprising resistor R10 and thermistor 23. Thermistor 23 has a negative temperature coefficient and the voltage at node N6 is determined by the following equation:

VN6=Vcc(TH1/(TH1+R10)

where R10 is the resistance value of resistor R10 and TH1 is the resistance value of the thermistor at a given temperature.

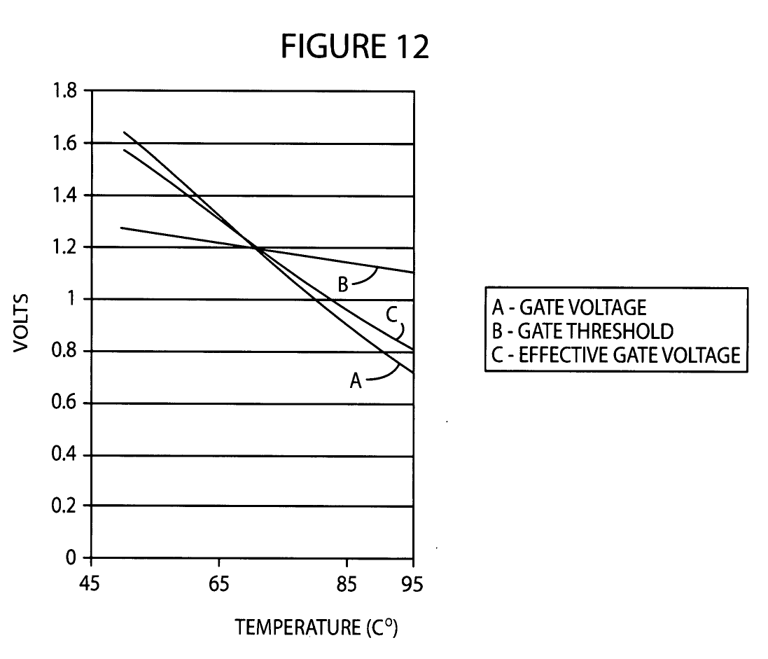

FIG. 12 is a graph of voltage versus temperature for the gate voltage, the gate to source threshold voltage, and the effective gate voltage.

In FIG. 12, line A represents the voltage at the gate or thermistor voltage, line B represents the gate to source or threshold voltage and line C represents the effective gate voltage. The effective gate voltage C is the usable portion of the voltage applied by the thermistor to the gate. The graphs in FIG. 12 are shown for a Vcc voltage of 2.5 VDC.

The effective gate voltage C has a non-linear negative temperature coefficient. Therefore, as the temperature drops, the effective gate threshold voltage rises. This effect will reduce the control that FET transistor 18 (FIG. 2) has as the resistance of thermistor 23 (FIG. 2) increases as the temperature decreases.

In other words, the increase in gate threshold voltage of FET transistor 18 negates some of the voltage increase on the thermistor 23 as the temperature changes so that the control of the temperature in oven 32 is not directly proportional to the change in outside or ambient temperature.

The transconductance of the FET transistor 18 is a factor in the control of the oven. Transconductance is measured in Siemens (S) and is the ratio of the change in drain current divided by the change in gate voltage for a FET transistor.

The circuit design utilizes the combination of gate threshold voltage change and FET transconductance to operate the oven control with a loop gain of less than one. Therefore, the circuit is not designed and does not attempt to keep the oven temperature constant as opposed to prior art proportional oven controllers, which attempt to maintain a constant temperature. Thus, the heater response to a change in temperature is insufficient to maintain a relative constant temperature inside the oven.

Stated another way, the transistor voltage change and transconductance (gate threshold of the transistor 18 and thermistor 23) combine to provide insufficient gain to keep the temperature inside the oven 32 at a nearly constant temperature but allows the temperature inside the oven 32 to drop as the outside ambient temperature drops in a manner in which the temperature inside the oven 32 may or may not be linear with respect to the change in ambient temperature.

Proportional oven controllers can typically hold the oven temperature in a very narrow range from a few degrees to a few milli-degrees depending on oven design, insulation etc. Unfortunately, proportional controllers require larger amounts of power.

The use of the temperature sensor of the present invention to directly control the heater results in reduced power requirements as compared to devices of the prior art when the ambient temperature drops.

### Conclusion

One of ordinary skill in the art of oscillator design will realize many advantages from the use of the subject disclosed embodiments. Further, one of ordinary skill in the art of making oscillators will realize that there are many different ways of accomplishing the embodiments.

While the invention has been taught with specific reference to these embodiments, someone skilled in the art will recognize that changes can be made in form and detail without departing from the spirit and the scope of the invention. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

For example, it is understood that the oscillator structure as disclosed can be utilized with a proportional controlled heater system although it has been described herein for use in a system which does not utilize a proportional oven controller.

What is claimed is:

1. An oscillator assembly, comprising:
a printed circuit board having a first and second surface;
a substrate having a third and fourth surface;
an enclosure defining a temperature controlled oven, the printed circuit board and the substrate located within the enclosure;
a plurality of conductive balls electrically connected between the first surface and the fourth surface;
an oscillator circuit located on the third surface;
a temperature compensation circuit in communication with the oscillator circuit, the temperature compensation circuit located on the third surface;
a heater located on the third surface; and
a resonator mounted to the substrate and at least partially extending over the heater.

2. The oscillator assembly of claim 1, wherein a cover mounted over the substrate and to the printed circuit board defines the enclosure.

3. The oscillator assembly of claim 1, wherein the printed circuit board forms a first wall of the enclosure.

4. The oscillator assembly of claim 1, wherein a temperature sensor is mounted to the substrate.

5. The oscillator assembly of claim 1, wherein the heater further comprises a field effect transistor mounted to the substrate.

6. The oscillator assembly of claim 1, wherein the heater further comprises a plurality of resistors mounted to the substrate.

7. The oscillator assembly of claim 5, wherein the field effect transistor has a gate, a source, a drain, and a temperature sensor is coupled to the gate for controlling the field effect transistor.

8. The oscillator assembly of claim 4, wherein the heater is not controlled in direct proportion to a temperature measured by the temperature sensor.

9. A method of operating an oscillator, not all necessarily in the order shown comprising:
providing a temperature compensated crystal oscillator located within an enclosure, the temperature compensated crystal oscillator producing a frequency signal;
measuring a first temperature within the enclosure using a first temperature sensor;
controlling a field effect transistor using the first temperature sensor;
measuring a second temperature within the enclosure; and
adjusting the frequency signal based on the second temperature.

10. The method according to claim 9, wherein the field effect transistor has a gate, a source, and a drain, the first temperature sensor being connected to the gate.

11. The method according to claim 10, wherein the first temperature sensor comprises a thermistor.

12. The method according to claim 11, wherein the second temperature is measured using a second temperature sensor.

13. The method according to claim 11, wherein a gate threshold voltage change and transconductance combine to provide insufficient gain to keep the temperature inside the enclosure at a nearly constant temperature.

14. The method according to claim 9, wherein the first temperature within the enclosure is non-linear to an ambient temperature outside the enclosure.

15. An oscillator assembly, comprising:
a housing;
a substrate in the housing;
an oscillator circuit defined on the substrate;
a resonator in communication with the oscillator circuit;
a temperature compensation circuit defined on the substrate and in communication with the oscillator circuit;
a field effect transistor mounted to the substrate, the field effect transistor having a source, a gate, and a drain; and
a thermistor mounted to the substrate and connected to the gate, the thermistor being adapted to control a gate voltage in response to changes in temperature.

16. The oscillator assembly of claim 15, wherein the substrate is a ball grid array substrate.

17. The oscillator assembly of claim 16, wherein the ball grid array substrate has a plurality of conductive balls attached thereto.

18. The oscillator assembly of claim 17, wherein the conductor balls connect the substrate to a printed circuit board.

19. The oscillator assembly of claim 15, wherein the resonator is coupled to the substrate and overlies at least the field effect transistor and the thermistor.

20. An oscillator assembly, comprising:
an oscillator circuit configured to generate a frequency signal;
a temperature compensation circuit in communication with the oscillator circuit, the temperature compensation circuit being adapted to adjust the frequency signal in response to changes in temperature;
an oven, the oscillator circuit, and the temperature compensation circuit located within the oven;
a heater located in the oven; and
a temperature sensor located in the oven and in communication with the heater, the temperature sensor being adapted to control the heater in response to changes in temperature.

21. The oscillator assembly of claim 20, wherein the heater comprises a field effect transistor and a plurality of resistors.

22. The oscillator assembly of claim 21, wherein the field effect transistor has a gate, a source, and a drain.

23. The oscillator assembly of claim 22, wherein the temperature sensor comprises at least one thermistor that is coupled directly or indirectly to the gate.

24. The oscillator assembly of claim 22, wherein the response of the heater to a change in temperature is insufficient to maintain a relative constant temperature inside the oven.

25. The oscillator assembly of claim 22, wherein a gate threshold voltage change and transconductance combine to provide insufficient gain to keep the temperature inside the oven at a nearly constant temperature.

26. An oscillator assembly, comprising:
a first substrate defining a top surface;
a second substrate seated on the top surface of the first substrate, the second substrate defining a top surface;
an oscillator and temperature compensation circuit defined on the top surface of the second substrate;
a heater defined on the top surface of the second substrate;
a resonator overlying at least a portion of the top surface of the second substrate; and
a lid which encloses at least the resonator and the second substrate.

27. The oscillator assembly of claim 26, wherein the first substrate is a printed circuit board, the second substrate is a ball grid array substrate with conductive balls which couple the second substrate to the first substrate, the resonator is coupled to the second substrate, and the lid is coupled to the printed circuit board.

28. The oscillator assembly of claim 27, wherein the resonator overlies at least a heater defined on the top surface of the second substrate.

29. The oscillator assembly of claim 28, further comprising a transistor and thermistor defined on the top surface of the second substrate, such that the transistor and thermistor provide insufficient gain to keep the temperature inside the oscillator assembly at a nearly constant temperature.
